(19) United States
(12) Patent Application Publication
(10) Pub. No.: US 2026/0004017 A1
(43) Pub. Date: Jan. 1, 2026

(54) MULTI-OBJECTIVE OPTIMIZATION METHOD, DEVICE AND MEDIUM FOR STRUCTURAL PARAMETERS OF SUPERCONDUCTING CABLE

(71) Applicant: STATE GRID SHANGHAI MUNICIPAL ELECTRIC POWER CO., Shanghai (CN)

(72) Inventors: Ting JIAO, Shanghai (CN); Honglei LI, Shanghai (CN); Lei SU, Shanghai (CN); Aiqing MA, Shanghai (CN); Haoyang TIAN, Shanghai (CN); Qingchuan XU, Shanghai (CN); Shunning ZHANG, Shanghai (CN)

(21) Appl. No.: 19/322,606

(22) Filed: Sep. 8, 2025

Related U.S. Application Data
(63) Continuation of application No. PCT/CN2024/131453, filed on Nov. 12, 2024.

(30) Foreign Application Priority Data
Mar. 26, 2024 (CN) 202410347386.7
Nov. 12, 2024 (WO) PCT/CN2024/131453

(51) Int. Cl. G06F 30/18; H01B 12/02

(52) U.S. Cl. CPC G06F 30/18; H01B 12/02

(57) ABSTRACT

A multi-objective optimization method for structural parameters of a superconducting cable, comprising steps of: S1, obtaining structural parameters and performance parameters of the superconducting cable, setting a constraint range of the structural parameters of the superconducting cable, based on the structural parameters and performance parameters of the superconducting cable, constructing an objective function, to establish a multi-objective optimization model of the structural parameters of the superconducting cable; and S2, through an improved multi-objective grey wolf optimization algorithm, iteratively solving the multi-objective optimization model of the structural parameters of the superconducting cable, to obtain an optimal solution for each of the structural parameters of the superconducting cable; where, to an iteration coefficient in a multi-objective grey wolf optimization algorithm, a weight coefficient negatively correlated with an overall sensitivity index of each of the structural parameters of the superconducting cable is given, to obtain the improved multi-objective grey wolf optimization algorithm.

### CROSS-REFERENCE TO RELATED APPLICATIONS

This application is a continuation of International Application No. PCT/CN2024/131453, filed on Nov. 12, 2024, which claims priority to Chinese Patent Application No. CN202410347386.7, filed on Mar. 26, 2024, and patented as No. CN118246324B, the contents of which are incorporated herein by reference in their entirety.

### TECHNICAL FIELD

The disclosure relates to the technical field of power transmission and power distribution, particularly to a multi-objective optimization method, device, and medium for the structural parameters of superconducting cable.

### BACKGROUND

During the operation of a superconducting cable, hysteresis loss will occur due to the magnetic field transformation caused by AC current. In order to maintain the normal working temperature of the superconducting cable, the cooling system needs to consume at least 15 times the electric energy, to remove the heat generated by the part of the AC loss from the system. Therefore, optimizing the cable structure, reducing AC loss, and controlling the cooling cost of the system are important factors to be considered in the structural design of superconducting cable. Besides affecting the cooling cost, the optimization of cable structure also directly affects the usage of superconducting tape. The production and preparation cost of superconducting tape is high, so it is also very important to reasonably control the amount of tape. The results show that increasing the winding angle of tape can reduce the AC loss, but it will also increase the amount of tape. In order to obtain the optimal superconducting cable structure, it is necessary to balance multiple objective functions.

The conventional related art discloses a rapid optimization method for the superconducting cable structure. Through the particle swarm optimization algorithm, the rapid optimization for the cold-insulated high-temperature superconducting cable structural parameters is completed, and each of the structural parameters of the high-temperature superconducting cable can be accurately obtained, which improves the research and development efficiency and the accuracy of the high-temperature superconducting cable. Although the particle swarm algorithm performs well in terms of convergence speed, when dealing with large-scale optimization problems, the convergence speed of the algorithm may be affected due to the need to calculate the velocity and position of a large number of particles. In addition, during the search process of particle swarm algorithm, if the particles in the swarm converge to the vicinity of the local optimal solution prematurely, especially, when dealing with complex multi-modal function optimization problems, it may cause the whole swarm to fall into the local optimal solution and fail to find the global optimal solution.

The Multi-objective Grey Wolf Optimizer (MOGWO) algorithm, which simulates the hunting behavior of the grey wolves, focuses on maintaining the diversity of solution space in the optimization process, and is easy to understand and apply. It is often used to deal with complex optimization problems with multiple parameters and multiple objectives, such as superconducting cable structure optimization. However, when using the MOGWO algorithm to process the structure optimization model of superconducting cable, the more tape layers, the more parameters are involved, the longer the iterative screening process of the algorithm will be, and the calculation time will increase exponentially. Therefore, it is necessary to improve the MOGWO algorithm to improve the convergence speed and the optimization effect when solving the optimization problem for superconducting cable structural parameters.

### SUMMARY

The object of the disclosure is to provide a multi-objective optimization method, device, and medium for the structural parameters of the superconducting cable, in order to overcome the defects existing in the related arts, and improve the optimization speed and optimization effect for the structural parameters of the superconducting cable.

The object of the present disclosure can be achieved by the following technical solutions:

A multi-objective optimization method for structural parameters of a superconducting cable, comprising steps of:
S1, obtaining structural parameters and performance parameters of the superconducting cable, setting a constraint range of the structural parameters of the superconducting cable, based on the structural parameters and performance parameters of the superconducting cable, constructing an objective function, to establish a multi-objective optimization model of the structural parameters of the superconducting cable; and
S2, through an improved multi-objective grey wolf optimization algorithm, iteratively solving the multi-objective optimization model of the structural parameters of the superconducting cable, to obtain an optimal solution for each of the structural parameters of the superconducting cable;
where, to an iteration coefficient in a multi-objective grey wolf optimization algorithm, a weight coefficient negatively correlated with an overall sensitivity index of each of the structural parameters of the superconducting cable is given, to obtain the improved multi-objective grey wolf optimization algorithm.

Further, the structural parameters of the superconducting cable comprises: a number of tapes in each layer, a winding angle of each layer, and a radius of the innermost conductive layer.

Further, the objective function comprises: a superconducting cable AC loss and a superconducting tape length.

Further, the iteration coefficient in the multi-objective grey wolf optimization algorithm comprises: one or more of an individual position contraction and expansion coefficient A, and an active exploration degree C. within a certain random range around the individual.

Further, the multi-objective optimization model of the structural parameters of the superconducting cable is analyzed by a Sobol analysis method, and the overall sensitivity index of each of the structural parameters of the superconducting cable is obtained.

Further, the multi-objective optimization model of the structural parameters of the superconducting cable comprises: a plurality of objective functions. Each of the objective functions is an analyzed by the Sobol analysis method, to obtain the overall sensitivity index of each of the structural parameter of the superconducting cable under each of the objective functions, and the weight coefficient is generated based on a reciprocal of an average value of the overall sensitivity index of all the objective functions.

Further, the step of, through the improved multi-objective grey wolf optimization algorithm, iteratively solving the multi-objective optimization model of the structural parameters of the superconducting cable, comprises:
S201, randomly generating an initial population, non-dominatedly sorting the initial population, and establishing a non-dominated solution set Archive;
S202, based on the weight coefficient generated by the overall sensitivity index of each of the structural parameters of the superconducting cable, updating the iteration coefficient in the multi-objective grey wolf optimization algorithm;
S203, based on the iteration coefficient, updating the position of each individual in the population and updating the non-dominated solution set Archive;
S204, determining whether an iteration termination condition is satisfied, and if so, proceeding to step S205, if not, returning to step S203; and
S205, outputting the non-dominated solution set Archive, solving an Euclidean distance of each of the non-dominated solutions after fitness normalizing, and selecting the non-dominated solution with a smallest Euclidean distance as an optimal solution to output.

Further, in step S204, the iteration termination condition is that a preset maximum number of iterations is reached.

The present disclosure also provides an electronic device comprising a memory, a processor, and a program stored in the memory, and the processor implements the method when executing the program.

The present disclosure also provides a computer-readable storage medium having a computer program stored thereon, and when executed by a processor, the program implements the above method.

Compared with the related arts, the disclosure has the following beneficial effects:
1. In the disclosure, the iterative coefficient in the multi-objective grey wolf optimization algorithm is assigned with the weight coefficient generated based on the reciprocal of the overall sensitivity index of each structural parameter of the superconducting cable, and the improved multi-objective grey wolf optimization algorithm is obtained, so as to solve the multi-parameter and multi-objective complex optimization problem of structural parameter of the superconducting cable. For the structural parameters of superconducting cables that have a great influence on the objective function, smaller iteration coefficients are employed in the iteration process to improve the search accuracy within the constraint range and avoid missing the optimal solution. Also, the structural parameters of superconducting cables that have little influence on the objective function employ the larger iteration coefficients in the iteration process, so as to cover the whole constraint space more quickly, accelerate the optimization speed, and avoid falling into the local optimal solution. The improved multi-objective grey wolf optimization algorithm, with personalized iteration for different structural parameters of the superconducting cable, can significantly improve the convergence speed and optimization effect of the multi-objective grey wolf optimization algorithm when solving the multi-objective superconducting cable structural parameter optimization problem.
2. The disclosure, through the Sobol analysis method, analyzes the multi-objective optimization model of the structural parameters of the superconducting cable, obtains the overall sensitivity index of each structural parameter of the superconducting cable, can effectively determine the key structural parameters affecting the performance of the multi-objective optimization model of the structural parameters of the superconducting cable, and analyzes the interaction effect between the structural parameters, which is convenient to understand and optimize the complex nonlinear multi-objective model.

### BRIEF DESCRIPTION OF THE DRAWINGS

FIG. 1 is a flowchart of the method of the present disclosure.

FIG. 2 is a diagram of the Sobol analysis results of AC loss.

FIG. 3 is a diagram of the Sobol analysis results of tape length.

FIG. 4 is a flowchart of the improved multi-objective grey wolf optimization algorithm.

FIG. 5 is the diagram of the convergence results of the multi-objective grey wolf optimization algorithm before and after optimization with different iterative coefficients;
where (5a) illustrating a non-optimized case, (5b) illustrating a case where only the individual position contraction and expansion coefficient A is optimized, (5c) illustrating a case where only the active exploration degree C. within a certain random range around the individual is optimized, and (5d) illustrating a case where the individual position contraction and expansion coefficient A and the active exploration degree C. within a certain random range around the individual are optimized simultaneously.

### DETAILED DESCRIPTION OF THE EMBODIMENTS

The present disclosure will be described in detail below with reference to the accompanying drawings and specific embodiments. This embodiment is implemented on the premise of the technical solution of the present disclosure, and detailed embodiments and specific operation procedures are given, but the scope of protection of the present disclosure is not limited to the following embodiments.

### Embodiment One

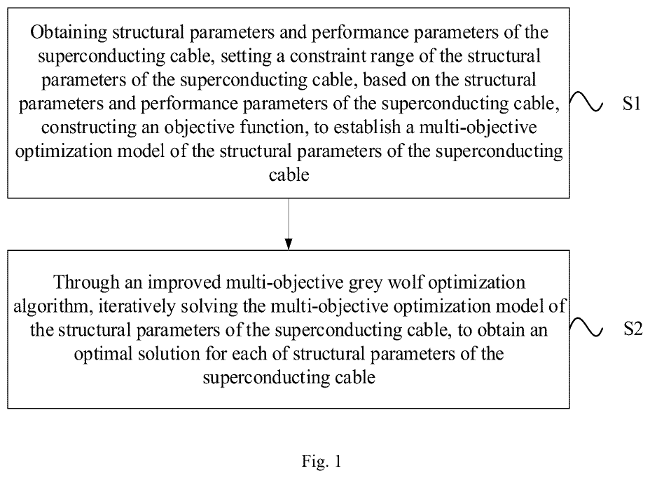

The embodiment provides a multi-objective optimization method for structural parameters of the superconducting cable, which optimizes structural parameters of a 35 kV/2.2 kA three-phase turnkey superconducting cable, as shown in FIG. 1, and the method comprises steps of:
S1, obtaining structural parameters and performance parameters of the superconducting cable, setting a constraint range of the structural parameters of the superconducting cable, based on the structural parameters and performance parameters of the superconducting cable, constructing an objective function, to establish a multi-objective optimization model of the structural parameters of the superconducting cable; and
S2, through an improved multi-objective grey wolf optimization algorithm, iteratively solving the multi-objective optimization model of the structural parameters of the superconducting cable, to obtain an optimal solution for each of the structural parameters of the superconducting cable.

The 35 kV/2.2 kA three-phase turnkey superconducting cable comprises 4 layers of superconducting tapes, which are a superconducting tape-shield layer, an insulating layer, a superconducting tape-conductive layer, and a semiconductive layer from outside to inside. In the embodiment, the number of tapes in each layer is set to n1, n2, n3, and n4, respectively, the winding angles of each layer are θ1, θ2, θ3, and θ4, respectively, and the radius of the innermost layer is R, with a total of 9 structural parameters, and the multi-objective optimization model of the structural parameters of the superconducting cable is established by taking the AC loss Q of the superconducting cable and the Length of the superconducting tape as two objective functions. The specific calculation equations of the two objective functions are as follows:

$$Q = {Q}_{N} + {Q}_{mag}$$

$${Q}_{N} = {\sum }_{i = 1}^{n} f {N}_{i} \frac{{μ}_{0} {I}_{c}^{2}}{π} ( ( 1 - {i}_{ac} ) ln ( 1 - {i}_{ac} ) + ( 1 + {i}_{ac} ) ln ( 1 + {i}_{ac} ) - {i}_{ac}^{2} )$$

$${i}_{ac} = I / {I}_{c}$$

$${Q}_{mag} = {\sum }_{i = 1}^{n} \frac{2 f {B}_{i}^{2}}{{μ}_{0}} \frac{{β}_{i}}{3} {S}_{i}$$

$${β}_{i} = \frac{{B}_{i}}{{μ}_{0} {J}_{C}^{b}}$$

$$Length = {\sum }_{i = 1}^{n} {N}_{i} * ( {L}_{0} / cos ( {θ}_{i} ) )$$

where Q_{N} is the self-field transmission loss of superconducting tape, Nᵢ is the number of tapes in each layer, f is the frequency, μ₀ is the vacuum permeability, I is the load current of tape, I_{c} is the critical current of superconducting tape, i_{ac} is the normalized current, Q_{mag} is the external field magnetization loss of superconducting cable, Bᵢ is the magnetic induction intensity, βᵢ is the normalized magnetic field, Sᵢ is the cross-sectional area of superconducting tape, J_{C} is the critical current density of superconducting tape, b is a half of the width of superconducting tape, L₀ is the cable length, and θᵢ is the winding angle of the i-th layer.

Then, the calculated results are compared in the form of Euclidean distance to select the optimal solution:

$$P = min \sqrt{( {( Q / {Q}_{max} )}^{2} + {( Length / {Length}_{max} )}^{2} )}$$

Limited by the stress of the tape, the variation range of the winding angles θ1, θ2, θ3, and θ4 of each layer is set to 5° to 35°. Limited by the cross-sectional area of the copper skeleton of the superconducting cable, the variation range of the winding radius R of the innermost tape is set to 11.45 mm to 12.45 mm. Limited by the width and critical current density of superconducting tape under a certain winding radius, the variation ranges of the number of tape n1, n2, n3, and n4 in each layer are ([11, 14], [11, 14], [19, 22], and [20, 23]), respectively.

In the multi-objective grey wolf optimization (MOGWO) algorithm, the core iterative process (prey encircling process in grey wolf group hunting behavior) is: based on positions of the three optimal leader solutions α, β and δ, adjusting the other individual positions X. Take the iterative process of adjusting the individual position X based on the α solution position as an example (the iterative process based on β and δ solutions is the same and only the subscript is changed), as shown in the following equation:

$$\vec{D} = \vert \vec{C} \cdot {\vec{X}}_{a} ( t ) - \vec{X} ( t ) \vert$$

$$\vec{A} = 2 \vec{a} \cdot {\vec{r}}_{1} - \vec{a}$$

$$\vec{a} = 2 - t * ( 2 / {t}_{max} )$$

$$\vec{C} = 2 \cdot {\vec{r}}_{2}$$

$${\vec{X}}_{a} ( t + 1 ) = {\vec{X}}_{a} ( t ) - \vec{A} \cdot \vec{D}$$

where D represents the distance between the individual and the α solution position, t is the number of iterations, fmax is the maximum number of iterations, which is set to 300 in this embodiment, X_{α}(t) is the α solution position at the 1-th iteration, X(t) is the other individual position solved at the t-th iteration, a is the convergence factor, which linearly decreases from 2 to 0 with the increase of the number of iterations, and rᵢ and r₂ are random numbers between [0, 1]. Therefore, A as an individual position contraction and expansion coefficient varies in the range of [−2, 2]. That is, in a case where |A|>1, the individual will move away from the α wolf position, and in a case where |A|<1, the individual will move close to the α wolf position. That is, the first half of the optimization tends to search the whole space, while the second half tends to converge to the optimal solution. C represents the active exploration degree within a certain random range around the individual.

The next position of the three leaders α, β, and δ is synthesized to update the next iteration position X(t+1) of other individuals, as shown in the following equation:

$$\vec{X} ( t + 1 ) = \frac{\vec{{X}_{α}} ( t + 1 ) + \vec{{X}_{β}} ( t + 1 ) + \vec{{X}_{δ}} ( t + 1 )}{3}$$

It can be seen from the above equation that, for each structural parameter in the superconducting cable, the iteration coefficients A and C have the same values in the iteration process. The global search is also performed in the same step length. However, in the study of the influence characteristics of single variable on AC loss of superconducting cable, it is found that different parameters have different influence degrees on AC loss. Therefore, the iterative process should also be adjusted differently based on the sensitivity of different parameters. The disclosure analyzes to obtain the normalized overall sensitivity of each parameter by Sobol analysis, to respectively assign a weight coefficient to the iteration coefficient in the random iteration process, as shown in the following equation:

$${\vec{{r}_{1}}}^{′} = {[ \begin{matrix}\frac{1}{{S}_{T 1}} & \frac{1}{{S}_{T 2}} & \frac{1}{{S}_{T 3}} & … … & \frac{1}{{S}_{T n}}\end{matrix} ]}^{′} * \vec{{r}_{1}}$$

$${\vec{{r}_{2}}}^{′} = {[ \begin{matrix}\frac{1}{{S}_{T 1}} & \frac{1}{{S}_{T 2}} & \frac{1}{{S}_{T 3}} & … … & \frac{1}{{S}_{T n}}\end{matrix} ]}^{′} * \vec{{r}_{2}}$$

where S_{T1}, S_{T2}, . . . , S_{Tn} represent the normalized overall sensitivity index of each parameter.

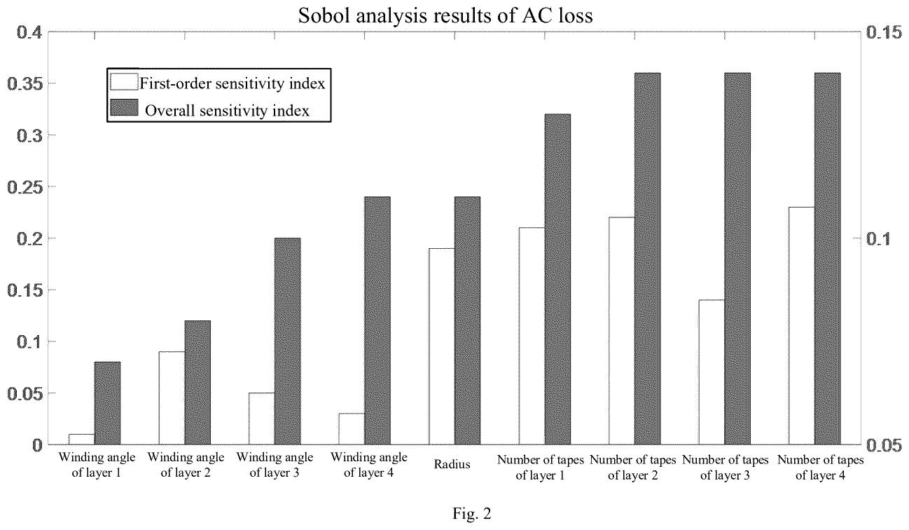

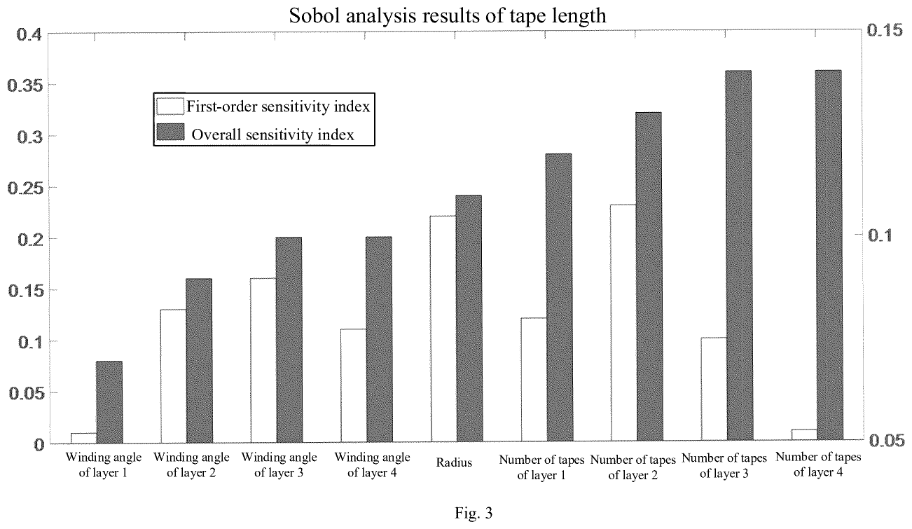

With the Sobol analysis method, the parameter multi-objective optimization model of superconducting cable structure is analyzed, and the sensitivity analysis results under the two objective functions are shown in FIG. 2 and FIG. 3 respectively. It can be seen that, in the two objective functions calculation model, the first-order sensitivity index distribution of the 9 input structural parameters is disordered, due to the high nonlinearity in the calculation process. In the two objective functions calculation model, the overall sensitivity index of structural parameters shows a gradual increasing trend. This shows that when considering the interaction and nonlinear relationship between parameters, the calculation model makes a more comprehensive and specific response to different parameters. Compared with the winding angle of each layer, the number of superconducting tapes in each layer can significantly affect the AC loss. Therefore, the average value of the overall sensitivity index of the two objective functions is taken as the optimization basis of the equation coefficients, as follows:

$${\vec{{r}_{1}}}^{′} = {[ \begin{matrix}\frac{1}{0.8} & \frac{1}{0.9} & \frac{1}{1} & \frac{1}{1.1} & \frac{1}{1.1} & \frac{1}{1.2} & \frac{1}{1.3} & \frac{1}{1.3} & \frac{1}{1.3}\end{matrix} ]}^{′} * \vec{{r}_{1}}$$

$${\vec{{r}_{2}}}^{′} = {[ \begin{matrix}\frac{1}{0.8} & \frac{1}{0.9} & \frac{1}{1} & \frac{1}{1.1} & \frac{1}{1.1} & \frac{1}{1.2} & \frac{1}{1.3} & \frac{1}{1.3} & \frac{1}{1.3}\end{matrix} ]}^{′} * \vec{{r}_{2}}$$

Through the above adjustment, the parameters that have great influence on the objective function can be smaller random magnitudes in the iterative process, so as to improve the search accuracy of parameters within the constraint range and avoid missing the optimal solution. Also, the parameters that have less influence on the objective function can be larger random magnitudes in iteration, to cover the whole constraint space more quickly, so as to accelerate the optimization speed and avoid falling into the local optimal solution.

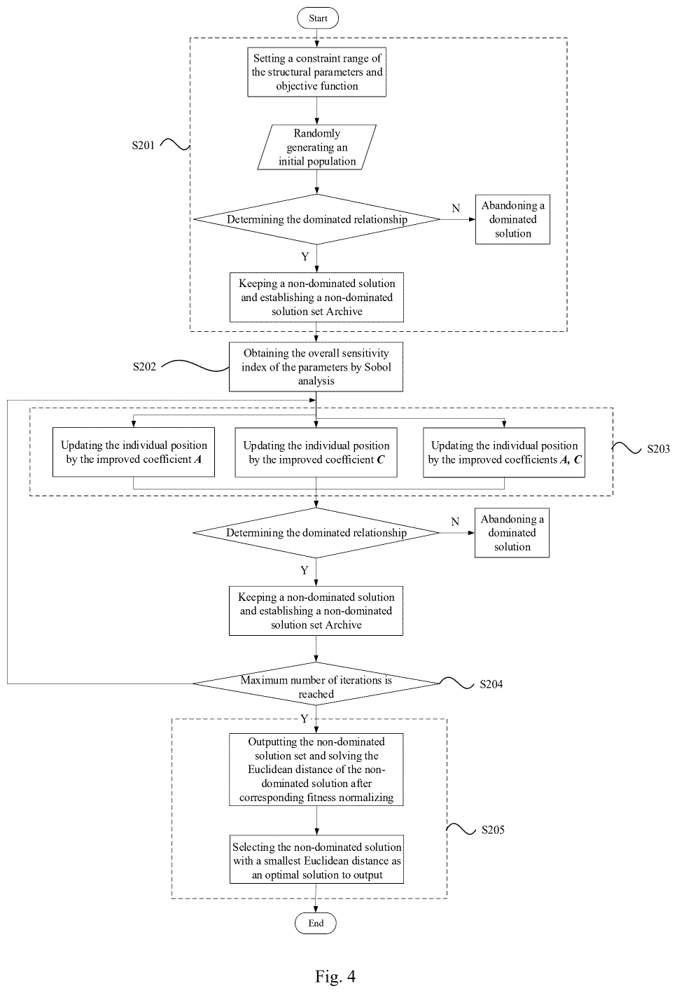

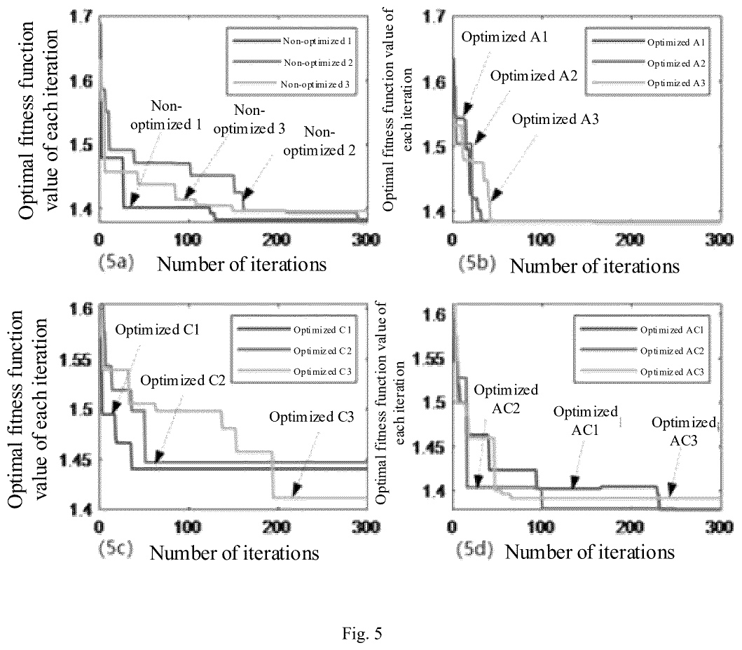

The optimized MOGWO algorithm flow is shown in FIG. 4. Through the improved multi-objective grey wolf optimization algorithm, the specific process of iteratively solving the multi-objective optimization model of the structural parameters of the superconducting cable is as follows:
S201, randomly generating an initial population, non-dominatedly sorting the initial population to abandon a dominated solution and keep a non-dominated solution, and establishing a non-dominated solution set Archive;
S202, based on the weight coefficient generated by the overall sensitivity index of each of the structural parameters of the superconducting cable, updating the iteration coefficient in the multi-objective grey wolf optimization algorithm;
S203, based on the iteration coefficient, updating the position of each individual in the population and updating the non-dominated solution set Archive;
S204, determining whether a maximum number of iterations is reached, and if so, proceeding to step S205, if not, returning to step S203;
S205, outputting the non-dominated solution set Archive, solving an Euclidean distance of each of the non-dominated solutions after fitness normalizing, and selecting the non-dominated solution with a smallest Euclidean distance as an optimal solution to output.

The improved algorithm, with personalized iteration for different structural parameters of the superconducting cable, can significantly improve the convergence speed and optimization effect of the MOGWO algorithm when solving the multi-objective superconducting cable structural parameter optimization problem. In order to verify the effectiveness of the method of the disclosure, the convergence iterative effects of the conventional MOGWO algorithm (coefficients A and C are not optimized), only optimizing coefficient A, only optimizing coefficient C, and simultaneously optimizing coefficients A and C are compared. The results are shown in (5a), (5b), (5c), and (5d) of FIG. 5, respectively. Due to the limitation of random numbers in intelligent optimization algorithms, the speed of iterative convergence to obtain the optimal solution and the converged optimal solution can be different in each optimization process. Therefore, in each case, the structural parameter optimization is carried out three times. It can be seen that the number of iterations of the converged optimal solution by the traditional MOGWO algorithm is distributed around 120 to 200. After optimizing the coefficient A three times, the number of iterations of the optimal solution converged by the optimization program is stably distributed below 50, and the convergence speed of the program is greatly improved, and the convergence effect is good. After optimizing the coefficient C three times, it does not optimize the convergence speed of the program, or even can't converge to the optimal solution, and the optimization effect is poor. After the coefficients A and C are optimized three times simultaneously, the number of iterations of the optimal solution converged by the optimization program is about 100 to 200, and the convergence speed improvement effect is not significant, and the optimization effect is unstable. From the above comparison, it can be seen that optimizing the coefficient A in the optimization program of the MOGWO algorithm can significantly improve the convergence speed and optimization effect of the MOGWO algorithm.

In order to verify the accuracy of the convergence results of the proposed MOGWO algorithm based on the improved coefficient A, the optimization results obtained by the MOGWO algorithm based on the improved coefficient A are compared with the 35 kV/2.2 kA three-phase turnkey superconducting cable structure operated in the existing literature (Zhang Xize, Zong Xihua, Huang Yijia. Design and Research of Shanghai Kilometer-level Superconducting Cable [J]. Low Temperature and Superconducting, 2022, 50 (06): 35-41). The results are shown in Table 1.

TABLE 1
Structural Parameters of Three-Phase Turnkey Superconducting
Cable Before and After Optimization

| | | | Improved | |
|---|---|---|---|---|
| | | | MOGWO | |
| | | Reference | algorithm | |
| | | value | results | Error |
| Radius (mm) R | | 11.95 | 12.35 | 3.3% |
| Conductive | Winding angle θ1 | 6.49 | 5.75 | −11.4% |
| layer 1 | Number of tapes n1 | 14 | 14 | 0 |
| Conductive | Winding angle θ2 | 14.6 | 14.8 | 1.4% |
| layer 2 | Number of tapes n2 | 14 | 14 | 0 |
| Shield layer 1 | Winding angle θ3 | 11.47 | 10.66 | −7% |
| | Number of tapes n3 | 22 | 22 | 0 |
| Shield layer 2 | Winding angle θ4 | 7.25 | 6.56 | −9.5% |
| | Number of tapes n4 | 23 | 22 | −4.3% |

| | | | |
|---|---|---|---|
| Tape usage (km) | 267.1 | 266.7 | −0.15% |
| AC Loss (W) | 7034 | 6935 | −1.4% |

It can be seen from Table 1 that, as a whole, the structural parameters obtained by the improved MOGWO algorithm based on the optimization coefficient A have little error compared with the structural parameters of the three-phase turnkey superconducting cable obtained in the existing literature (i.e., the reference values in the table).

Thus on the basis that the conventional MOGWO algorithm processes the nonlinear multi-objective model, the disclosure assigns a weight coefficient based on parameter sensitivity to the iteration coefficient A thereof, which is helpful for the global optimization algorithm to explore space and actively converge, so as to find the global optimal solution faster and better, and can significantly improve the optimization speed and the optimization effect in the actual optimization problem of multi-parameters and multi-objectives.

### Embodiment Two

The present embodiment provides an electronic device, comprising one or more processors and a memory, where one or more programs are stored in the memory, and instructions for executing all or part of the steps of the multi-objective optimization method for structural parameters of a superconducting cable as described in Embodiment One are provided.

The foregoing description of the embodiments is to facilitate understanding and use of the disclosure by one having ordinary skill in the art. It will be apparent to those skilled in the art that various modifications can readily be made to these embodiments and that the general principles described herein can be applied to other embodiments without inventive effort. Therefore, the present disclosure is not limited to the above-described embodiments, and improvements and modifications made by those skilled in the art according to the disclosure of the present disclosure without departing from the scope of the present disclosure should be within the scope of protection of the present disclosure.

What is claimed is:

1. A multi-objective optimization method for structural parameters of a superconducting cable, comprising steps of:
S1, obtaining structural parameters and performance parameters of the superconducting cable, setting a constraint range of the structural parameters of the superconducting cable, based on the structural parameters and performance parameters of the superconducting cable, constructing an objective function, to establish a multi-objective optimization model of the structural parameters of the superconducting cable; and
S2, through an improved multi-objective grey wolf optimization algorithm, iteratively solving the multi-objective optimization model of the structural parameters of the superconducting cable, to obtain an optimal solution for each of the structural parameters of the superconducting cable;
wherein, to an iteration coefficient in a multi-objective grey wolf optimization algorithm, a weight coefficient negatively correlated with an overall sensitivity index of each of the structural parameters of the superconducting cable is given, to obtain the improved multi-objective grey wolf optimization algorithm.

2. The multi-objective optimization method for structural parameters of the superconducting cable according to claim 1, wherein
the structural parameters of the superconducting cable comprise: a number of tapes in each layer, a winding angle of each layer, and a radius of an innermost conductive layer.

3. The multi-objective optimization method for structural parameters of the superconducting cable according to claim 1, wherein
the objective function comprises: a superconducting cable AC loss and a superconducting tape length.

4. The multi-objective optimization method for structural parameters of the superconducting cable according to claim 1, wherein
the iterative coefficients in the multi-objective grey wolf optimization algorithm comprise one or more of: an individual position contraction and expansion coefficient A, and an active exploration degree C. within a certain random range around the individual.

5. The multi-objective optimization method for structural parameters of the superconducting cable according to claim 1, wherein
the multi-objective optimization model of the structural parameters of the superconducting cable is analyzed by a Sobol analysis method to obtain the overall sensitivity index of each structural parameter of the superconducting cable.

6. The multi-objective optimization method for structural parameters of the superconducting cable according to claim 5, wherein the multi-objective optimization model of superconducting cable structural parameters comprises: a plurality of objective functions; and
wherein the method further comprises: analyzing each of the objective functions by the Sobol analysis method, to obtain the overall sensitivity index of each of the structural parameters of the superconducting cable under each of the objective functions, and based on a reciprocal of an average value of the overall sensitivity index of all the objective functions, generating the weight coefficient.

7. The multi-objective optimization method for structural parameters of the superconducting cable according to claim 1, wherein the step of, through an improved multi-objective grey wolf optimization algorithm, iteratively solving the multi-objective optimization model of the structural parameters of the superconducting cable, comprises:
S201, randomly generating an initial population, non-dominatedly sorting the initial population, and establishing a non-dominated solution set;
S202, based on the weight coefficient generated by the overall sensitivity index of each of the structural parameters of the superconducting cable, updating the iteration coefficient in the multi-objective grey wolf optimization algorithm;
S203, based on the iteration coefficient, updating the position of each individual in the population and updating the non-dominated solution set;
S204, determining whether an iteration termination condition is satisfied, and if so, proceeding to step S205, if not, returning to step S203; and
S205, outputting the non-dominated solution set, solving an Euclidean distance of each of the non-dominated solutions after fitness normalizing, and selecting the non-dominated solution with a smallest Euclidean distance as an optimal solution to output.

8. The multi-objective optimization method for structural parameters of the superconducting cable according to claim 7, wherein in the step S203, the iteration termination condition is: a preset maximum number of iterations is reached.

9. An electronic device, comprising a memory, a processor, and a program stored in the memory, wherein the processor implements the method according to claim 1 when executing the program.

10. A computer-readable storage medium having a computer program stored thereon, wherein the program, when executed by a processor, implements a method according to claim 1.
